(19) United States
(12) Patent Application Publication
(10) Pub. No.: US 2024/0396516 A1
(43) Pub. Date: Nov. 28, 2024

(54) BALANCED-TO-UNBALANCED TRANSFORMER CIRCUIT, BALANCED-TO-UNBALANCED IMPEDANCE TRANSFORMER CIRCUIT, AND RADIO-FREQUENCY POWER AMPLIFIER

(71) Applicant: Murata Manufacturing Co., Ltd., Kyoto-fu (JP)

(72) Inventors: Seiko NETSU, Nagaokakyo-shi (JP); Masatoshi HASE, Nagaokakyo-shi (JP)

(73) Assignee: Murata Manufacturing Co., Ltd., Kyoto-fu (JP)

(21) Appl. No.: 18/792,234

(22) Filed: Aug. 1, 2024

Related U.S. Application Data
(63) Continuation of application No. PCT/JP2022/041204, filed on Nov. 4, 2022.

(30) Foreign Application Priority Data
Feb. 4, 2022 (JP) 2022-016369

(51) Int. Cl. H03H 7/42; H03F 3/24; H03F 3/45

(52) U.S. Cl. CPC H03H 7/42; H03F 3/245; H03F 3/45475; H03F 2200/06; H03F 2200/451

(57) ABSTRACT

A balanced-to-unbalanced transformer circuit is formed with a transmission line including a main line and a sub-line which are coupled to each other. The main line comprises at least one wiring line. The sub-line comprises multiple wiring lines which are connected in parallel to one another and which are other than the at least one wiring line. Each of the wiring lines of the sub-line is coupled to the at least one wiring line of the main line.

### CROSS-REFERENCE TO RELATED APPLICATIONS

This application claims benefit of priority to International Patent Application No. PCT/JP2022/041204, filed Nov. 4, 2022, and to Japanese Patent Application No. 2022-016369, filed Feb. 4, 2022, the entire contents of each are incorporated herein by reference.

### BACKGROUND

### Technical Field

The present disclosure relates to a balanced-to-unbalanced transformer circuit, a balanced-to-unbalanced impedance transformer circuit, and a radio-frequency power amplifier.

### Background Art

In a radio-frequency circuit, a balanced-to-unbalanced transformer circuit may be formed with a transmission line. A document by Chris Trask, entitled “Transmission Line Transformers: Theory, Design and Applications—Part 2”, High Frequency Electronics, January 2006 (the Non Patent Document) discloses a choke balun which performs balanced-to-unbalanced transformation with a transformation ratio of 1:1. The choke balun is formed with a transmission line including a main line and a sub-line which are coupled to each other.

### SUMMARY

In the choke balun disclosed in the Non Patent Document reference above, the amplitudes of differential signals are easily unbalanced. This is because coupling between the main line and the sub-line is insufficient. Accordingly, the present disclosure provides a balanced-to-unbalanced transformer circuit which enables the degree of amplitude imbalance in differential signals to be improved. The present disclosure also provides a balanced-to-unbalanced impedance transformer circuit and a radio-frequency power amplifier which include the balanced-to-unbalanced transformer circuit.

According to an aspect of the present disclosure, a balanced-to-unbalanced transformer circuit formed with a transmission line including a main line and a sub-line which are coupled to each other is provided. The main line comprises at least one wiring line. The sub-line comprises a plurality of wiring lines connected in parallel to one another, the plurality of wiring lines being other than the at least one wiring line, and each of the plurality of wiring lines of the sub-line is coupled to the at least one wiring line of the main line.

According to another aspect of the present disclosure, a balanced-to-unbalanced impedance transformer circuit is provided. The balanced-to-unbalanced impedance transformer circuit comprises a balanced-to-unbalanced transformer circuit that is formed with a transmission line including a main line and a sub-line which are coupled to each other, and a Ruthroff transmission line transformer that is connected to an output end, for a single-ended signal, of the balanced-to-unbalanced transformer circuit. The sub-line of the balanced-to-unbalanced transformer circuit comprises a plurality of wiring lines connected in parallel to one another, and each of the plurality of wiring lines of the sub-line is coupled to the main line of the balanced-to-unbalanced transformer circuit.

According to still another aspect of the present disclosure, a radio-frequency power amplifier is provided. The radio-frequency power amplifier comprises the balanced-to-unbalanced impedance transformer circuit described above, a differential-power amplifier circuit that outputs differential signals from differential-signal output nodes, and a power supply circuit that supplies power to the differential-power amplifier circuit. The differential-signal output nodes of the differential-power amplifier circuit are connected to the differential-signal input nodes of the balanced-to-unbalanced transformer circuit of the balanced-to-unbalanced impedance transformer circuit.

A sub-line comprises two wiring lines connected in parallel to each other, and the two wiring lines of the sub-line are coupled to a main line, causing the coupling strength between the main line and the sub-line to be increased. As a result, the degree of amplitude imbalance in differential signals may be improved.

### BRIEF DESCRIPTION OF THE DRAWINGS

FIG. 1 is an equivalent circuit diagram of a balanced-to-unbalanced transformer circuit according to a first embodiment example;

FIG. 2 is a schematic perspective view of the positional relationship between a main line and a sub-line of a balanced-to-unbalanced transformer circuit according to the first embodiment example;

FIG. 3 is an equivalent circuit diagram of a balanced-to-unbalanced transformer circuit according to a comparison example;

FIG. 4 is a schematic perspective view of the positional relationship between a main line and a sub-line of a balanced-to-unbalanced transformer circuit according to the comparison example illustrated in FIG. 3;

FIG. 5 is a graph of a simulation result of transmission coefficients S31 and S32 of balanced-to-unbalanced transformer circuits according to the first embodiment example (FIG. 1) and the comparison example (FIG. 3);

FIG. 6 is a graph of calculation results of the degrees of amplitude imbalance S31/S32 of balanced-to-unbalanced transformer circuits according to the first embodiment example (FIG. 1) and the comparison example (FIG. 3);

FIG. 7 is a graph of a simulation result of common-mode rejection ratios (CMRRs) of balanced-to-unbalanced transformer circuits according to the first embodiment example (FIG. 1) and the comparison example (FIG. 3);

FIG. 8 is a graph of a simulation result of the degrees of phase imbalance of balanced-to-unbalanced transformer circuits according to the first embodiment example (FIG. 1) and the comparison example (FIG. 3);

FIGS. 9A and 9B are graphs of simulation results of fractional bandwidths obtained from changes in the line widths W and the line lengths L of balanced-to-unbalanced transformer circuits according to the comparison example (FIG. 3) and the first embodiment example (FIG. 1), respectively;

FIG. 10 is an equivalent circuit diagram of a balanced-to-unbalanced transformer circuit according to another comparison example;

FIG. 11 is a graph of a simulation result of the degrees of amplitude imbalance of balanced-to-unbalanced transformer circuits according to the comparison example in FIG. 3 and the comparison example in FIG. 10;

FIG. 12 is a schematic perspective view of the positional relationship between a main line and a sub-line of a balanced-to-unbalanced transformer circuit according to a second embodiment example;

FIG. 13 is a schematic perspective view of the positional relationship between a main line and a sub-line of a balanced-to-unbalanced transformer circuit according to a comparison example;

FIG. 14 is a schematic perspective view of the positional relationship between a main line and a sub-line of a balanced-to-unbalanced transformer circuit according to another comparison example;

FIG. 15 is a schematic perspective view of the positional relationship between a main line and a sub-line of a balanced-to-unbalanced transformer circuit according to a third embodiment example;

FIG. 16 is a graph of a simulation result of the degrees of amplitude imbalance of balanced-to-unbalanced transformer circuits according to the first embodiment example (FIG. 2) and the third embodiment example (FIG. 15);

FIG. 17 is a graph of a simulation result of fractional bandwidths of a balanced-to-unbalanced transformer circuit according to the third embodiment example;

FIG. 18 is an equivalent circuit diagram of a balanced-to-unbalanced transformer circuit according to a fourth embodiment example;

FIG. 19 is a graph of a simulation result of fractional bandwidths obtained from changes in the line width W and the line length L of each wiring line of a main line and a sub-line of a balanced-to-unbalanced transformer circuit according to the fourth embodiment example;

FIG. 20 is a graph of a simulation result of the degrees of amplitude imbalance of balanced-to-unbalanced transformer circuits according to the fourth embodiment example (FIG. 18) and the comparison example (FIG. 3);

FIG. 21 is an equivalent circuit diagram of a balanced-to-unbalanced transformer circuit according to a modified example of the fourth embodiment example;

FIG. 22 is a graph of a simulation result of fractional bandwidths obtained from changes in the line width W and the line length L of each wiring line of a main line and a sub-line of a balanced-to-unbalanced transformer circuit according to the modified example (FIG. 21) of the fourth embodiment example;

FIG. 23 is a graph of a simulation result of the degrees of amplitude imbalance of balanced-to-unbalanced transformer circuits according to the modified example (FIG. 21) of the fourth embodiment example and the comparison example (FIG. 3);

FIG. 24 is an equivalent circuit diagram of a balanced-to-unbalanced impedance transformer circuit according to a fifth embodiment example;

FIG. 25A is a schematic plan view of a wiring pattern of a main line and a sub-line of a balanced-to-unbalanced transformer circuit and those of a Ruthroff transmission line transformer, which are used in a balanced-to-unbalanced impedance transformer circuit according to the fifth embodiment example; and FIG. 25B is a schematic plan view of a wiring pattern of a main line and a sub-line of a balanced-to-unbalanced transformer circuit and those of a Ruthroff transmission line transformer, which are used in a balanced-to-unbalanced impedance transformer circuit according to a modified example of the fifth embodiment example;

FIGS. 26A and 26B are schematic plan views of wiring patterns of main lines and sub-lines of balanced-to-unbalanced transformer circuits and those of Ruthroff transmission line transformers, which are used in balanced-to-unbalanced impedance transformer circuits according to other modified examples of the fifth embodiment example;

FIGS. 27A and 27B are schematic plan views of wiring patterns of main lines and sub-lines of balanced-to-unbalanced transformer circuits and those of Ruthroff transmission line transformers, which are used in balanced-to-unbalanced impedance transformer circuits according to yet other modified examples of the fifth embodiment example;

FIG. 28 is an equivalent circuit diagram of a balanced-to-unbalanced impedance transformer circuit according to a sixth embodiment example;

FIG. 29 is an equivalent circuit diagram of a balanced-to-unbalanced impedance transformer circuit according to a modified example of the sixth embodiment example;

FIG. 30 is a schematic perspective view of the positional relationship between a main line and a sub-line of the Ruthroff transmission line transformer used in a balanced-to-unbalanced impedance transformer circuit according to the modified example (FIG. 29) of the sixth embodiment example;

FIG. 31 is an equivalent circuit diagram of a balanced-to-unbalanced impedance transformer circuit according to another modified example of the sixth embodiment example;

FIG. 32 is an equivalent circuit diagram of a balanced-to-unbalanced impedance transformer circuit according to a seventh embodiment example;

FIG. 33 is an equivalent circuit diagram of a radio-frequency power amplifier according to an eighth embodiment example;

FIG. 34A is a graph of a simulation result of transmission coefficients obtained in the case where differential signals are received at differential-signal input nodes Nin+ and Nin− of a radio-frequency power amplifier according to the eighth embodiment example and where a single-ended signal is output from an output node Nout; and FIG. 34B is a graph of a simulation result of common-mode rejection ratios of a radio-frequency power amplifier according to the eighth embodiment example;

FIG. 35 is an equivalent circuit diagram of a radio-frequency power amplifier according to a modified example of the eighth embodiment example; and

FIG. 36 is an equivalent circuit diagram of a radio-frequency power amplifier according to another modified example of the eighth embodiment example.

### DETAILED DESCRIPTION

### First Embodiment Example

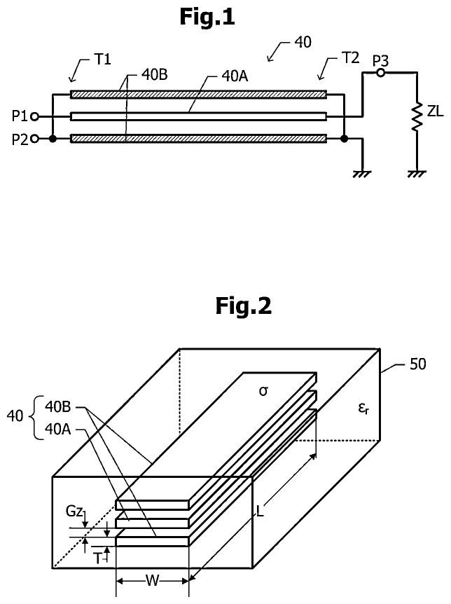

Referring to the drawings of FIGS. 1 to 11, a balanced-to-unbalanced transformer circuit according to a first embodiment example will be described.

FIG. 1 is an equivalent circuit diagram of a balanced-to-unbalanced transformer circuit 40 according to the first embodiment example. The balanced-to-unbalanced transformer circuit 40 according to the first embodiment example is formed with a transmission line including a main line 40A and a sub-line 40B which are coupled to each other. The sub-line 40B comprises two wiring lines connected in parallel to each other, and each of the two wiring lines is coupled to the main line 40A. The expression, “two wiring lines connected in parallel to each other”, means wiring lines which are connected so that a current flowing into a single node is split to two wiring lines, and that the currents flowing through the two wiring lines join at a different node. The main line 40A comprises a single wiring line. One end portion of the transmission line is called a first end T1, and the other end portion is called a second end T2.

The main line 40A is connected, at the first end T1, to a first node P1, and is connected, at the second end T2, to a third node P3. The two wiring lines of the sub-line 40B are connected, at the first end T1, to a second node P2, and are connected, at the second end T2, to the ground potential. A load ZL is connected between the third node P3 and the ground potential. When differential signals are input to the first node P1 and the second node P2, a single-ended signal is output from the third node P3.

FIG. 2 is a schematic perspective view of the positional relationship between the main line 40A and the sub-line 40B of the balanced-to-unbalanced transformer circuit 40 according to the first embodiment example. The two wiring lines of the sub-line 40B and the main line 40A are disposed in three corresponding wiring layers in a multilayer wiring substrate 50. The wiring line of the main line 40A is interposed between the two wiring lines of the sub-line 40B in the thickness direction of the multilayer wiring substrate 50. In plan view, the wiring line of the main line 40A almost completely overlaps each of the two wiring lines of the sub-line 40B. In FIG. 2, the main line 40A and the sub-line 40B are illustrated as having a straight-line shape in plan view. However, they may have a shape extending along the outline of a circle or a polygon in plan view.

The main line 40A and the two wiring lines of the sub-line 40B have the same width which is denoted as W. The main line 40A and the two wiring lines of the sub-line 40B have the same thickness which is denoted as T. The spaces between the main line 40A and the two wiring lines of the sub-line 40B are the same, and are denoted as Gz. The main line 40A and the two wiring lines of the sub-line 40B have the same length which is denoted as L. The relative dielectric constant of the multilayer wiring substrate 50 is denoted as εᵣ. The conductivities of the main line 40A and the sub-line 40B are denoted as σ.

Excellent effects of the first embodiment example will be described.

The sub-line 40B of a balanced-to-unbalanced transformer circuit according to the first embodiment example comprises two wiring lines connected in parallel to each other. Each of the two wiring lines is coupled to the main line 40A. Therefore, compared with the case in which the sub-line 40B comprises a single wiring line, the coupling strength between the main line 40A and the sub-line 40B is increased. Thus, the transmission coefficient S32 from the second node P2 to the third node P3 is increased. In addition, the interconnect resistance of the main line 40A is approximately double that of the sub-line 40B. Thus, the transmission coefficient S31 from the first node P1 to the third node P3 is decreased relatively.

This achieves such an excellent effect that the degree of amplitude imbalance −S31/S32 [dB] of the balanced-to-unbalanced transformer circuit 40 approaches 0 dB.

Results of simulations performed to confirm the excellent effects of the first embodiment example will be described. In the simulations, various characteristics of a balanced-to-unbalanced transformer circuit according to the first embodiment example are compared with those of a balanced-to-unbalanced transformer circuit of a comparison example.

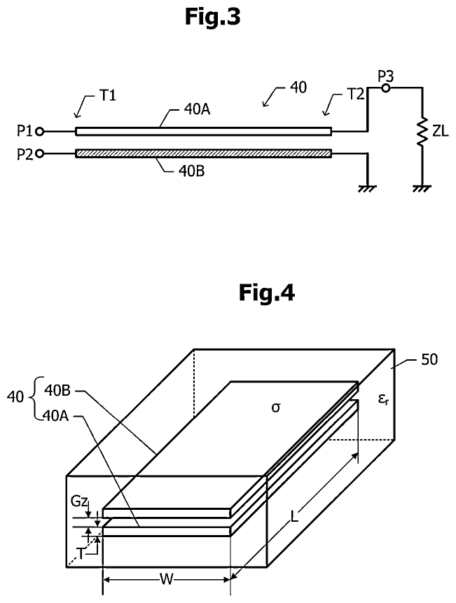

FIG. 3 is an equivalent circuit diagram of a balanced-to-unbalanced transformer circuit 40 according to the comparison example. In the comparison example, the sub-line 40B comprises a single wiring line. FIG. 4 is a schematic perspective view of the positional relationship between the main line 40A and the sub-line 40B of the balanced-to-unbalanced transformer circuit 40 according to the comparison example in FIG. 3. The main line 40A and the sub-line 40B are disposed in two wiring layers adjacent to each other in the thickness direction of the multilayer wiring substrate 50.

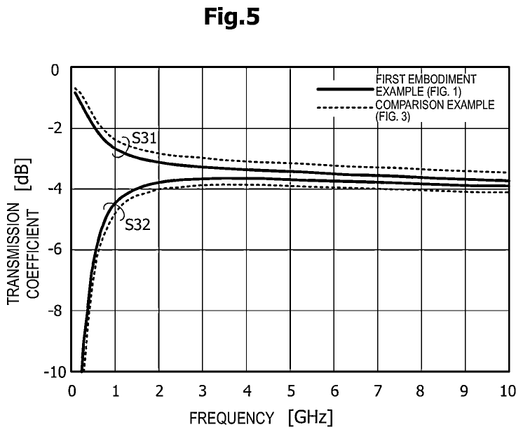

FIG. 5 is a graph of the simulation result of the transmission coefficients S31 and S32 of the balanced-to-unbalanced transformer circuits according to the first embodiment example (FIG. 1) and the comparison example (FIG. 3). The horizontal axis represents frequency in the units of [GHz]; the vertical axis represents the transmission coefficients S31 and S32 in the units of [dB]. The solid lines and the dashed lines in the graph indicate the transmission coefficients S31 and S32 of the balanced-to-unbalanced transformer circuits 40 according to the first embodiment example (FIG. 1) and the comparison example (FIG. 3), respectively.

The simulation condition is as follows the line length L of each of the main line 40A and the sub-line 40B according to the first embodiment example and the comparison example=2000 μm; the line width W of each of the main line 40A and the sub-line 40B according to the first embodiment example=25 μm; the line width W of each of the main line 40A and the sub-line 40B according to the comparison example=45 μm; the thickness T of each of the main line 40A and the sub-line 40B according to the first embodiment example and the comparison example=3 μm; the space Gz between the main line 40A and the sub-line 40B according to the first embodiment example and the comparison example=3 μm; the conductivity σ of each of the main line 40A and the sub-line 40B according to the first embodiment example and the comparison example=5.9×107 S/m; and the relative dielectric constant εᵣ of the multilayer wiring substrate 50=3.9. The line length L and the line width W according to the first embodiment example and the comparison example were set so that the fractional bandwidth is made high at a frequency of 4150 MHz.

The transmission coefficient S32 of the balanced-to-unbalanced transformer circuit 40 according to the first embodiment example is higher than that according to the comparison example. This is because, in the first embodiment example, the sub-line 40B, which comprises two wiring lines connected in parallel to each other, causes the coupling strength between the main line 40A and the sub-line 40B to be increased. The transmission coefficient S31 of the balanced-to-unbalanced transformer circuit 40 according to the first embodiment example is lower than that according to the comparison example. This is because the interconnect resistance of the main line 40A according to the first embodiment example is higher than that according to the comparison example.

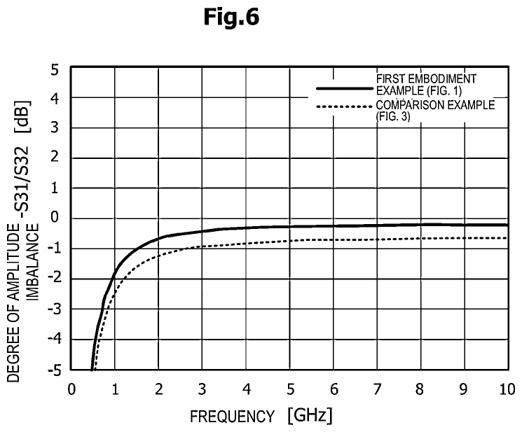

FIG. 6 is a graph of the calculation result of the degrees of amplitude imbalance −S31/S32 [dB] of the balanced-to-unbalanced transformer circuits 40 according to the first embodiment example (FIG. 1) and the comparison example (FIG. 3). The horizontal axis represents frequency in the units of [GHz]; the vertical axis represents the degree of amplitude imbalance −S31/S32 in the units of [dB]. The solid line and the dashed line in the graph indicate the degrees of amplitude imbalance of the balanced-to-unbalanced transformer circuits 40 according to the first embodiment example (FIG. 1) and the comparison example (FIG. 3), respectively. It is found that the configuration as in the first embodiment example (FIG. 1), in which the sub-line 40B comprises two wiring lines connected in parallel to each other, causes the degree of amplitude imbalance to be improved.

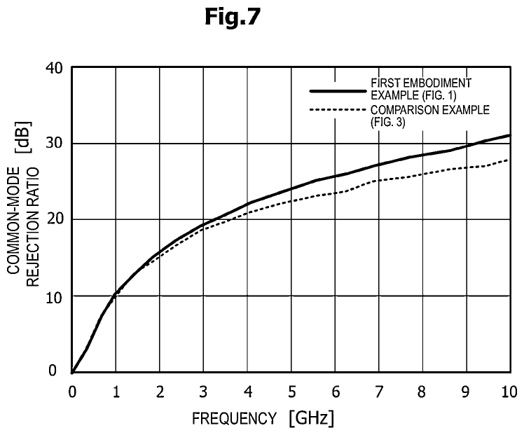

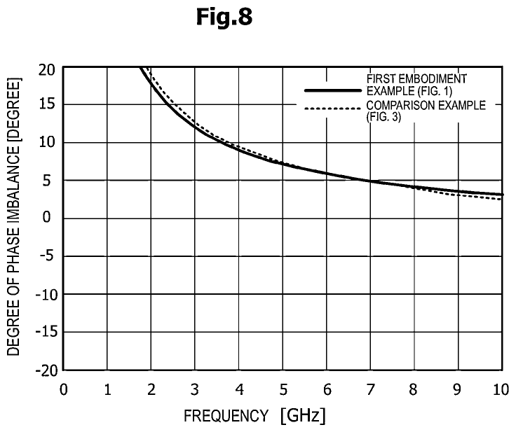

FIG. 7 is a graph of the simulation result of the common-mode rejection ratios (CMRRs) of the balanced-to-unbalanced transformer circuits 40 according to the first embodiment example (FIG. 1) and the comparison example (FIG. 3). The horizontal axis represents frequency in the units of [GHz]; the vertical axis represents common-mode rejection ratio in the units of [dB]. The solid line and the dashed line in the graph indicate the common-mode rejection ratios of the balanced-to-unbalanced transformer circuits 40 according to the first embodiment example (FIG. 1) and the comparison example (FIG. 3), respectively. It is found that, compared with the comparison example, the common-mode rejection ratio of the balanced-to-unbalanced transformer circuit 40 according to the first embodiment example is improved in the frequency range of approximately 3 GHz or greater.

FIG. 8 is a graph of the simulation result of the degrees of phase imbalance of the balanced-to-unbalanced transformer circuits 40 according to the first embodiment example (FIG. 1) and the comparison example (FIG. 3). The horizontal axis represents frequency in the units of [GHz]; the vertical axis represents the degree of phase imbalance in the units of [degree]. The solid line and the dashed line in the graph indicate the degrees of phase imbalance of the balanced-to-unbalanced transformer circuits 40 according to the first embodiment example (FIG. 1) and the comparison example (FIG. 3), respectively. It is found that a substantially equivalent degree of phase imbalance is obtained in the frequency range, which is greater than or equal to approximately 2 GHz and less than or equal to approximately 10 GHz (i.e., from approximately 2 GHz to approximately 10 GHz), in the first embodiment example and the comparison example (FIG. 3).

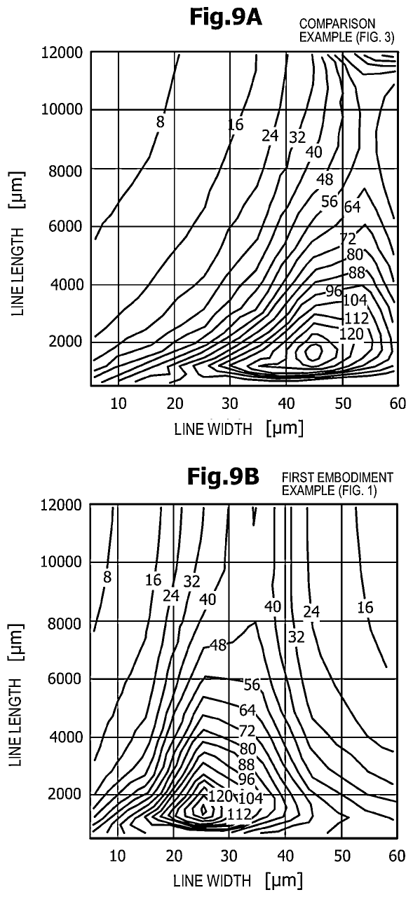

FIGS. 9A and 9B are graphs of the simulation results of the fractional bandwidths obtained from changes in the line widths W and the line lengths L of the balanced-to-unbalanced transformer circuits 40 according to the comparison example (FIG. 3) and the first embodiment example (FIG. 1), respectively. The horizontal axis represents the line width W in the units of [μm]; the vertical axis represents the line length L in the units of [μm]. The center frequency was set to 4150 MHz. The solid lines in the graphs indicate isopleths of the fractional bandwidth. The values assigned to the isopleths indicate the fractional bandwidth values in the units of [%]. The step size of the isopleths is 8%.

As is clear from the graph in FIG. 9A, in the comparison example, the line width W, with which the maximum fractional bandwidth is obtained, is approximately 45 μm. In contrast, as is clear from the graph in FIG. 9B, in the first embodiment example, the line width W, with which the maximum fractional bandwidth is obtained, is approximately 25 μm. Thus, compared with the comparison example, the optimum value of the line width W for achieving the maximum fractional bandwidth is lower in the first embodiment example. Therefore, compared with the comparison example, the volume, in which the transmission line is occupied in the multilayer wiring substrate 50, may be decreased in the first embodiment example. This may achieve a reduction in size of the balanced-to-unbalanced transformer circuit 40.

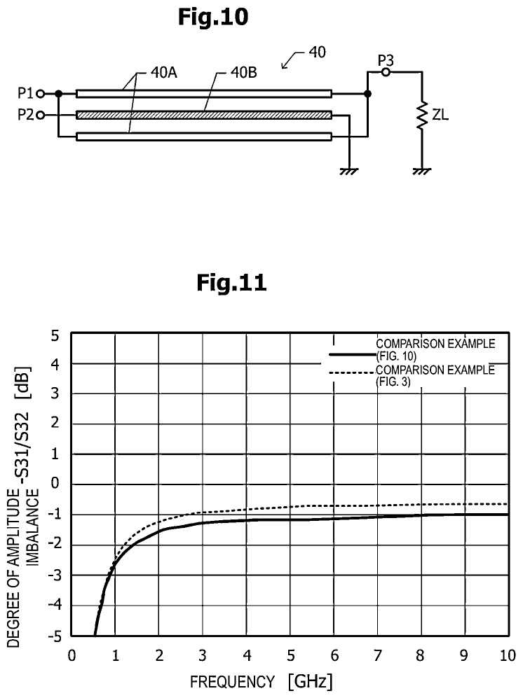

Referring to FIGS. 10 and 11, the reason why, in the first embodiment example, the sub-line 40B, not the main line 40A, comprises two wiring lines connected in parallel to each other will be described. In the first embodiment example, the sub-line 40B, which comprises two wiring lines, causes the coupling strength between main line 40A and the sub-line 40B to be increased. Alternatively, the main line 40A, not the sub-line 40B, may comprise two wiring lines, which are connected in parallel to each other, to increase the coupling strength.

FIG. 10 is an equivalent circuit diagram of a balanced-to-unbalanced transformer circuit 40 according to a comparison example. In the comparison example in FIG. 10, the main line 40A comprises two wiring lines connected in parallel to each other. The sub-line 40B comprises a single wiring line.

FIG. 11 is a graph of the simulation result of the degrees of amplitude imbalance of balanced-to-unbalanced transformer circuits 40 according to the comparison example in FIG. 3 and the comparison example in FIG. 10. The horizontal axis represents frequency in the units of [GHz]; the vertical axis represents the degree of amplitude imbalance −S31/S32 in the units of [dB]. The solid line and the dashed line in the graph indicate the degrees of amplitude imbalance of the balanced-to-unbalanced transformer circuits 40 according to the comparison example in FIG. 10 and the comparison example in FIG. 3, respectively. It is found that the degree of amplitude imbalance of the comparison example in FIG. 10 is degraded compared with the comparison example in FIG. 3. This is because, while an increase of the coupling strength between the main line 40A and the sub-line 40B causes the transmission coefficient S32 to be increased, a decrease of the interconnect resistance of the main line 40A causes the transmission coefficient S31 to be also increased.

The configuration as in the first embodiment example (FIG. 1), in which the sub-line 40B, not the main line 40A, comprises two wiring lines connected in parallel to each other, may cause the degree of amplitude imbalance to be improved.

### Second Embodiment Example

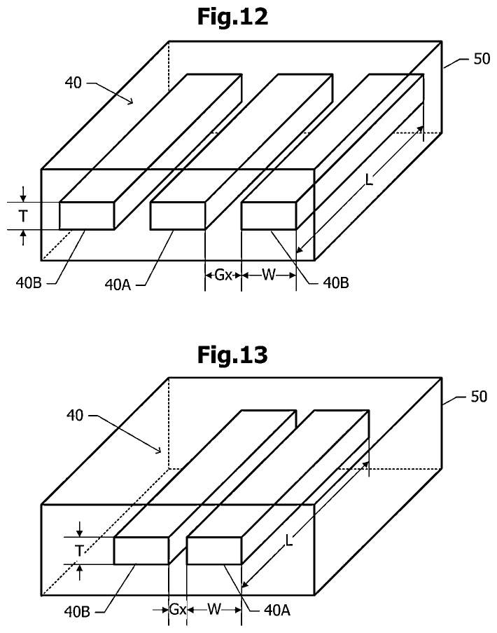

Referring to FIG. 12, a balanced-to-unbalanced transformer circuit according to a second embodiment example will be described. The configuration common to the balanced-to-unbalanced transformer circuit according to the first embodiment example, which is described by referring to the drawings of FIGS. 1 to 11, will not be described below.

FIG. 12 is a schematic perspective view of the positional relationship between the main line 40A and the sub-line 40B of a balanced-to-unbalanced transformer circuit 40 according to the second embodiment example. In the first embodiment example (FIG. 2), the wiring line, which is comprised by the main line 40A, is interposed between the two wiring lines, which are comprised by the sub-line 40B, in the thickness direction of the multilayer wiring substrate 50. In contrast, in the second embodiment example, the two wiring lines, which are comprised by the sub-line 40B, are disposed on both the sides of the wiring line, which is comprised by the main line 40A, in plan view of the multilayer wiring substrate 50. In other words, in plan view of the multilayer wiring substrate 50, the wiring line, which is comprised by the main line 40A, is interposed between the two wiring lines, which are comprised by the sub-line 40B, in the width direction which is orthogonal to the longitudinal direction of the wiring line.

The wiring line, which is comprised by the main line 40A, and the two wiring lines, which are comprised by the sub-line 40B, have the same width which is denoted as W. The wiring line, which is comprised by the main line 40A, and the two wiring lines, which are comprised by the sub-line 40B, have the same line length which is denoted as L. The wiring line, which is comprised by the main line 40A, and the two wiring lines, which are comprised by the sub-line 40B, have the same thickness which is denoted as T. The spaces between the main line 40A and the two wiring line, which are comprised by the sub-line 40B, are the same, and are denoted as Gx.

Excellent effects of the second embodiment example will be described in comparison with comparison examples.

FIGS. 13 and 14 are schematic perspective views of the positional relationships between the main lines 40A and the sub-lines 40B of balanced-to-unbalanced transformer circuits 40 according to the comparison examples. In each of the comparison examples in FIGS. 13 and 14, the main line 40A and the sub-line 40B, which each comprise a single wiring line, are disposed side by side in the in-plane direction of a multilayer wiring substrate 50.

In the comparison example in FIG. 13, the thickness T of each of the main line 40A and the sub-line 40B are equal to the thickness T of each of the main line 40A and the sub-line 40B of the balanced-to-unbalanced transformer circuit 40 according to the second embodiment example. In the optimum condition for maximizing the fractional bandwidth, the line space Gx in the second embodiment example (FIG. 12) is approximately double the line space Gx in the comparison example (FIG. 13). The minimum value of the line space Gx is restricted by a design rule of the multilayer wiring substrate 50. For example, when the space between wiring lines is too small for the design rule, the wiring lines may be in contact with each other. In the second embodiment example, the optimum value of the line space Gx is high. Thus, the possibility of implementing a transmission line of an optimum size without departing from the design rule is increased.

In the comparison example in FIG. 14, the line space Gx between the main line 40A and the sub-line 40B is equal to that of the balanced-to-unbalanced transformer circuit 40 according to the second embodiment example. In the optimum condition for maximizing the fractional bandwidth, the thickness T of each wiring line in the second embodiment example (FIG. 12) is approximately half that in the comparison example (FIG. 14). The maximum value of the thickness T of a wiring line is restricted by a process condition. In the second embodiment example, since the optimum value of the thickness T of each wiring line is low, the possibility of implementing a transmission line of an optimum size within the range in which the process condition is satisfied is increased.

### Third Embodiment Example

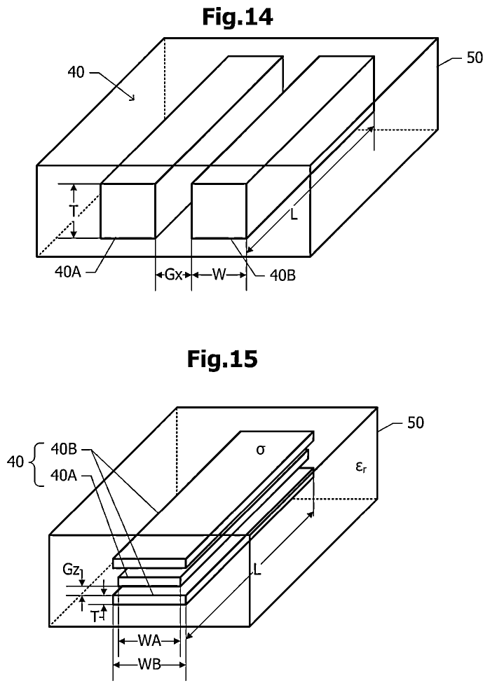

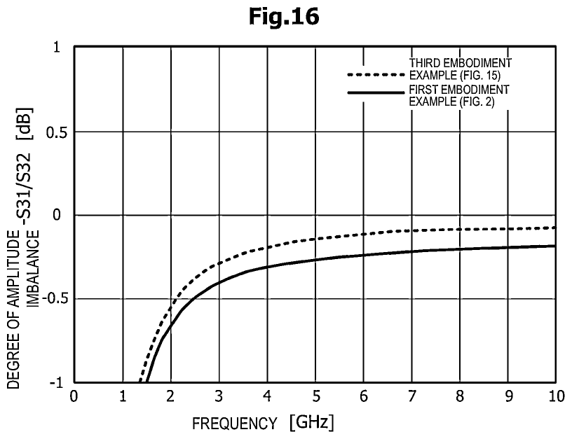

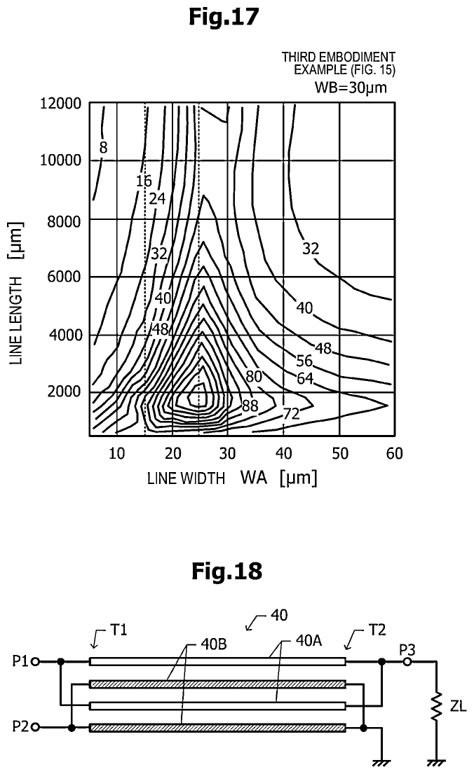

Referring to FIGS. 15, 16, and 17, a balanced-to-unbalanced transformer circuit according to a third embodiment example will be described. The configuration common to the balanced-to-unbalanced transformer circuit according to the first embodiment example, which is described by referring to the drawings of FIGS. 1 to 11, will not be described.

FIG. 15 is a schematic perspective view of the positional relationship between the main line 40A and the sub-line 40B of a balanced-to-unbalanced transformer circuit 40 according to the third embodiment example. In the first embodiment example (FIG. 2), the line width W of the main line 40A is equal to the line width W of each of the two wiring lines of the sub-line 40B. In contrast, in the third embodiment example, the line width WA of the main line 40A is smaller than the line width WB of each of the two wiring lines of the sub-line 40B.

Referring to FIG. 16, excellent effects of the third embodiment example will be described. FIG. 16 is a graph of the simulation result of the degrees of amplitude imbalance of the balanced-to-unbalanced transformer circuits 40 according to the first embodiment example (FIG. 2) and the third embodiment example (FIG. 15). The horizontal axis represents frequency in the units of [GHz]; the vertical axis represents the degree of amplitude imbalance −S31/S32 in the units of [dB]. The solid line and the dashed line in the graph indicate the degrees of amplitude imbalance of the balanced-to-unbalanced transformer circuits 40 according to the first embodiment example (FIG. 2) and the third embodiment example (FIG. 15), respectively.

The simulation condition of the balanced-to-unbalanced transformer circuit 40 according to the first embodiment example (FIG. 2) is the same as that for the degree of amplitude imbalance in FIG. 6. The simulation condition other than the line widths WA and WB of the balanced-to-unbalanced transformer circuit 40 according to the third embodiment example (FIG. 15) is the same as that according to the first embodiment example (FIG. 2). The line width WA of the main line 40A of the balanced-to-unbalanced transformer circuit 40 according to the third embodiment example (FIG. 15) was set to 20 μm; the line width WB of each of the two wiring lines of the sub-line 40B was set to 30 μm.

It is found that the degree of amplitude imbalance of the balanced-to-unbalanced transformer circuit 40 according to the third embodiment example is better than that according to the first embodiment example. This is because the main line 40A, which is made thin, causes the interconnect resistance of the main line 40A to be increased, resulting in a decrease of the transmission coefficient S31. As in the third embodiment example, the line width WA of the main line 40A is made smaller than the line width WB of each of the two wiring lines of the sub-line 40B, achieving a further enhanced effect of improving the degree of amplitude imbalance.

Referring to FIG. 17, a preferable lower limit of the line width WA of the main line 40A will be described.

The line width WA (FIG. 15) of the main line 40A, which is made small, causes the degree of amplitude imbalance to be improved. However, the fractional bandwidth may degrade because the characteristic impedance of the transmission line deviates from the optimum value.

FIG. 17 is a graph of the simulation result of the fractional bandwidth of the balanced-to-unbalanced transformer circuit 40 according to the third embodiment example. The horizontal axis represents the line width WA of the main line 40A in the units of [μm]; the vertical axis represents the line length L in the units of [μm]. The center frequency was set to 4150 MHz. The solid lines in the graph indicate isopleths of the fractional bandwidth. The values assigned to the isopleths indicate the fractional bandwidth values in the units of [%]. The step size of the isopleths is 8%. The simulation condition other than the line width WB of each of the two wiring lines of the sub-line 40B is the same as that according to the first embodiment example in FIG. 9B. The line width WB of each of the two wiring lines of the sub-line 40B was set to 30 μm.

The optimum characteristic impedance of a transmission line depends on the output impedances of differential-signal sources and the impedance of the load ZL (FIG. 1). For example, assume the case in which the output impedance of each of the two differential-signal sources is set to 5.5Ω, and in which the impedance of the load ZL is set to 11Ω. In this case, the optimum characteristic impedance is 11Ω. The line width WA of the main line 40A, with which the characteristic impedance of 11Ω is obtained, is approximately 25 μm.

As illustrated in FIG. 17, the line width WA of the main line 40A, with which the maximum fractional bandwidth is obtained, is approximately 25 μm. If the line width WA of the main line 40A is about 15 μm, the fractional bandwidth, which is about 50% of the maximum fractional bandwidth obtained when the line width WA is set to 25 μm, may be achieved. This value is comparable to the maximum fractional bandwidth obtained when a magnetic coupling transformer is used as a balanced-to-unbalanced transformer circuit. To ensure a desirable fractional bandwidth, the line width WA of the main line 40A is preferably set to half the line width WB of each of the two wiring lines of the sub-line 40B or greater.

### Fourth Embodiment Example

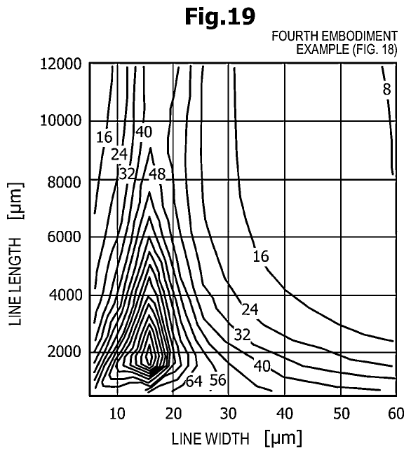

Referring to FIGS. 18, 19, and 20, a balanced-to-unbalanced transformer circuit according to a fourth embodiment example will be described. The configuration common to the balanced-to-unbalanced transformer circuit according to the first embodiment example, which is described by referring to the drawings of FIGS. 1 to 11, will not be described.

FIG. 18 is an equivalent circuit diagram of a balanced-to-unbalanced transformer circuit 40 according to the fourth embodiment example. In the first embodiment example (FIG. 1), the sub-line 40B comprises two wiring lines connected in parallel to each other, and the main line 40A comprises a single wiring line. In contrast, in the fourth embodiment example, each of the main line 40A and the sub-line 40B comprises two wiring lines connected in parallel to each other. One of the two wiring lines of the main line 40A is coupled to both the two wiring lines of the sub-line 40B; the other wiring line is coupled only to one of the wiring lines of the sub-line 40B.

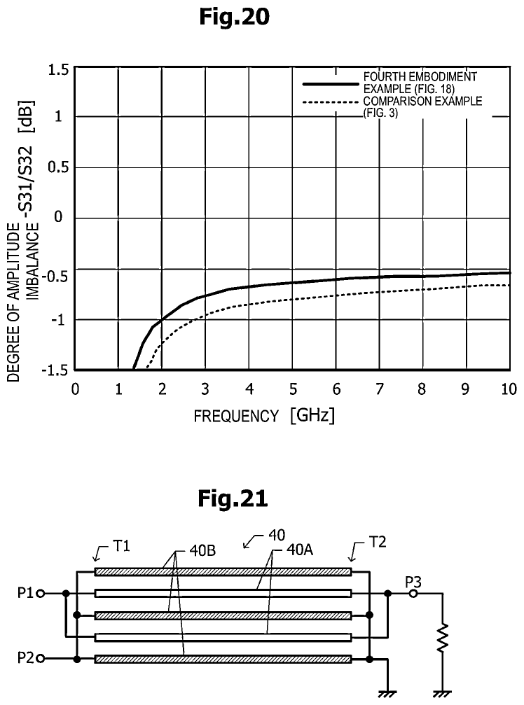

Referring to FIGS. 19 and 20, excellent effects of the fourth embodiment example will be described.

FIG. 19 is a graph of the simulation result of the fractional bandwidths obtained from changes in the line width W and the line length L of each wiring line of the main line 40A and the sub-line 40B of the balanced-to-unbalanced transformer circuit 40 according to the fourth embodiment example. The horizontal axis represents the line width W in the units of [μm]; the vertical axis represents the line length L in the units of [μm]. The center frequency was set to 4150 MHz. The solid lines in the graph indicate isopleths of the fractional bandwidth. The values assigned to the isopleths indicate the fractional bandwidth values in the units of [%]. The step size of the isopleths is 8%.

From FIG. 19, it is found that the optimum line width W, with which the maximum fractional bandwidth is obtained, is approximately 16 μm. In contrast, in the first embodiment example in FIG. 9B, the optimum line width W, with which the maximum fractional bandwidth is obtained, is approximately 25 μm. Thus, the configuration in which the main line 40A, as well as the sub-line 40B, comprises two wiring lines causes the optimum line width W for increasing the fractional bandwidth to be made small. Therefore, a reduction in size of the balanced-to-unbalanced transformer circuit 40 may be achieved.

FIG. 20 is a graph of the simulation result of the degrees of amplitude imbalance of the balanced-to-unbalanced transformer circuits 40 according to the fourth embodiment example (FIG. 18) and the comparison example (FIG. 3). The horizontal axis represents frequency in the units of [GHz]; the vertical axis represents the degree of amplitude imbalance −S31/S32 in the units of [dB]. The solid line and the dashed line in the graph indicate the degrees of amplitude imbalance of the balanced-to-unbalanced transformer circuits 40 according to the fourth embodiment example (FIG. 18) and the comparison example (FIG. 3), respectively. It is found that the degree of amplitude imbalance in the fourth embodiment example is better than that of the comparison example (FIG. 3).

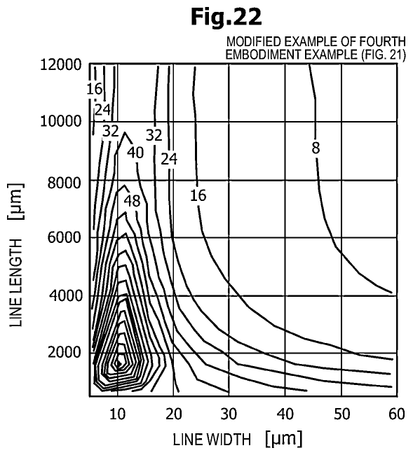

Referring to FIGS. 21, 22, and 23, a balanced-to-unbalanced transformer circuit according to a modified example of the fourth embodiment example will be described.

FIG. 21 is an equivalent circuit diagram of a balanced-to-unbalanced transformer circuit 40 according to the modified example of the fourth embodiment example. In the fourth embodiment example, the sub-line 40B comprises two wiring line connected in parallel to each other. In contrast, in the present modified example, the sub-line 40B comprises three wiring lines connected in parallel to one another. Each of the two wiring lines of the main line 40A is coupled to two of the three wiring lines of the sub-line 40B. One of the three wiring lines of the sub-line 40B is coupled to the two wiring lines of the main line 40A.

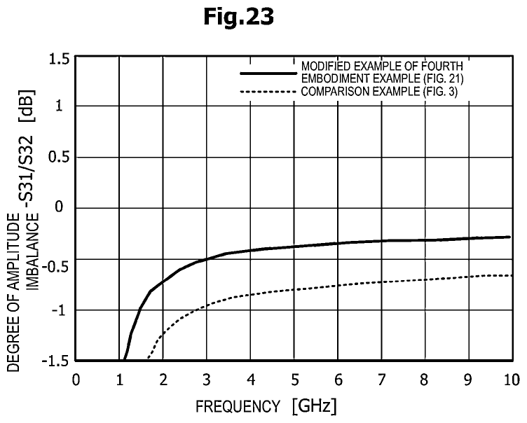

FIG. 22 is a graph which is similar to FIG. 19 and which illustrates the simulation result of fractional bandwidths obtained from changes in the line width W and the line length L of each wiring line of the main line 40A and the sub-line 40B of the balanced-to-unbalanced transformer circuit 40 according to the modified example (FIG. 21) of the fourth embodiment example. From FIG. 22, it is found that the optimum line width W, with which the maximum fractional bandwidth is obtained, is approximately 11 μm. Thus, in the modified example in FIG. 21, the optimum line width W for increasing the fractional bandwidth is made further smaller than that of the fourth embodiment example (FIG. 18). Therefore, a further reduction in size of the balanced-to-unbalanced transformer circuit 40 may be achieved.

FIG. 23 is a graph of the simulation result of the degrees of amplitude imbalance of the balanced-to-unbalanced transformer circuits 40 according to the modified example (FIG. 21) of the fourth embodiment example and the comparison example (FIG. 3). The horizontal axis represents frequency in the units of [GHz]; the vertical axis represents the degree of amplitude imbalance −S31/S32 in the units of [dB]. The solid line and the dashed line in the graph indicate the degrees of amplitude imbalance of the balanced-to-unbalanced transformer circuits 40 according to the modified example (FIG. 21) of the fourth embodiment example and the comparison example (FIG. 3), respectively. It is found that the degree of amplitude imbalance in the modified example of the fourth embodiment example is better than that of the comparison example (FIG. 3).

Another modified example of the fourth embodiment example will be described.

In the fourth embodiment example (FIG. 18), each of the main line 40A and the sub-line 40B comprises two wiring lines; in the modified example (FIG. 21) of the fourth embodiment example, the main line 40A comprises two wiring lines, and the sub-line 40B comprises three wiring lines. More generally speaking, each of the main line 40A and the sub-line 40B may comprise three or more wiring lines connected in parallel to one another. In this case, to suppress a relative increase of the transmission coefficient S31 with respect to the transmission coefficient S32, the number of wiring lines of the main line 40A is preferably less than or equal to that of the sub-line 40B. Further, to increase the coupling strength between the main line 40A and the sub-line 40B, at least one of the wiring lines of the main line 40A is preferably coupled to two wiring lines of the sub-line 40B.

### Fifth Embodiment Example

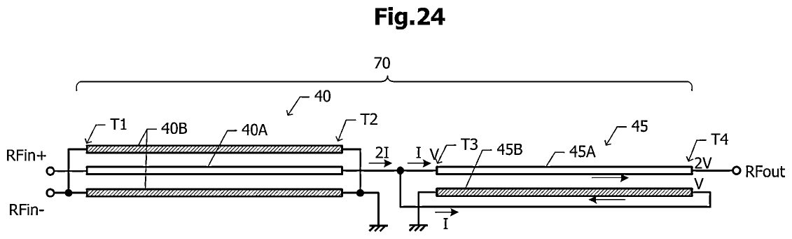

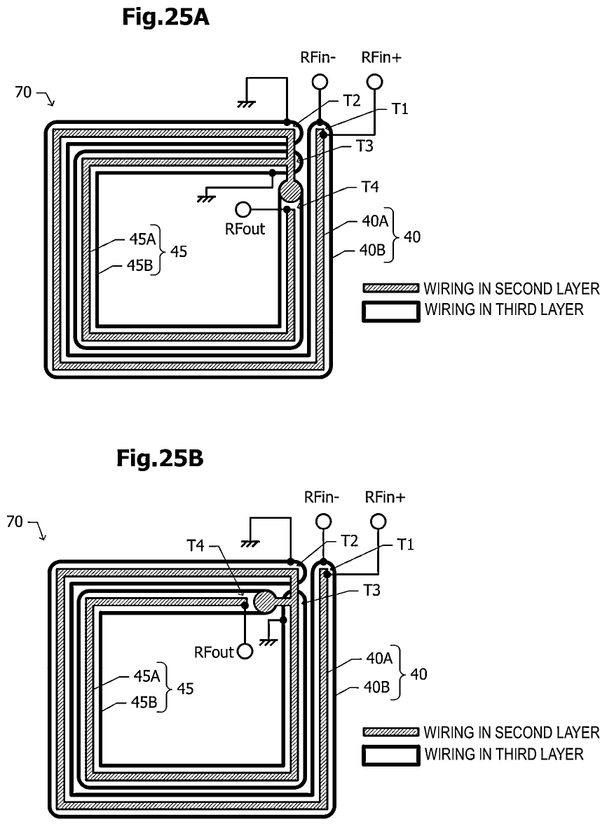

Referring to FIGS. 24 and 25A, a balanced-to-unbalanced impedance transformer circuit according to a fifth embodiment example will be described.

FIG. 24 is an equivalent circuit diagram of a balanced-to-unbalanced impedance transformer circuit 70 according to the fifth embodiment example. The balanced-to-unbalanced impedance transformer circuit 70 according to the fifth embodiment example includes the balanced-to-unbalanced transformer circuit 40 (FIG. 1) according to the first embodiment example and a Ruthroff transmission line transformer 45.

The Ruthroff transmission line transformer 45 is formed with a transmission line including a main line 45A and a sub-line 45B which are coupled to each other. One end portion of the transmission line constituting the Ruthroff transmission line transformer 45 is called a third end T3; the other end portion is called a fourth end T4. The main line 45A is connected, at the third end T3, to the fourth end T4 of the sub-line 45B. The sub-line 45B is connected, at the third end T3, to the ground potential. The main line 40A of the balanced-to-unbalanced transformer circuit 40 is connected, at the second end T2 (the output end of a single-ended signal), to the third end T3 of the main line 45A of the Ruthroff transmission line transformer 45.

When differential signals RFin+ and RFin− are received at the first end T1 of the main line 40A of the balanced-to-unbalanced transformer circuit 40 and the first end T1 of the sub-line 40B, the balanced-to-unbalanced transformer circuit 40 transforms the differential signals to a single-ended signal which is output from the second end T2 of the main line 40A. The single-ended signal, which is output from the balanced-to-unbalanced transformer circuit 40, is received at the third end T3 of the main line 45A of the Ruthroff transmission line transformer 45.

Odd-mode currents, whose magnitudes are the same, flow through the main line 45A and the sub-line 45B of the Ruthroff transmission line transformer 45. The magnitude of a current is represented by a multiplier with the symbol, I. The arrows, which are opposite to each other and which are assigned to the main line 45A and the sub-line 45B, indicate that odd-mode currents flow. The current, which is output from the second end T2 of the main line 40A of the balanced-to-unbalanced transformer circuit 40, is equally split to the main line 45A and the sub-line 45B of the Ruthroff transmission line transformer 45. Therefore, the current, which is output from the fourth end T4 of the main line 45A, is made half the current received by the Ruthroff transmission line transformer 45.

The potential difference between the third end T3 and the fourth end T4 of the main line 45A is equal to that between the third end T3 and the fourth end T4 of the sub-line 45B. In FIG. 24, the magnitude of a potential is represented by a multiplier with the symbol, V. Therefore, the voltage, which is output from the fourth end T4 of the main line 45A, is made double the voltage received by the Ruthroff transmission line transformer 45.

Thus, the Ruthroff transmission line transformer 45 of the balanced-to-unbalanced impedance transformer circuit 70 according to the fifth embodiment example performs impedance transformation with an impedance transformation ratio of 4:1. A single-ended signal RFout, which has been subjected to impedance transformation, is output from the fourth end T4 of the main line 45A of the Ruthroff transmission line transformer 45.

FIG. 25A is a schematic plan view of the wiring pattern of the main line 40A and the sub-line 40B of the balanced-to-unbalanced transformer circuit 40 and the main line 45A and the sub-line 45B of the Ruthroff transmission line transformer 45, which are used in the balanced-to-unbalanced impedance transformer circuit 70 according to the fifth embodiment example. The wiring lines, which are comprised by the main line 40A and the sub-line 40B of the balanced-to-unbalanced transformer circuit 40 and the main line 45A and the sub-line 45B of the Ruthroff transmission line transformer 45, are disposed in a common multilayer wiring substrate.

As illustrated in FIG. 3, in the balanced-to-unbalanced transformer circuit 40, one of the wiring lines of the sub-line 40B is disposed in the first layer; the wiring line of the main line 40A is disposed in the second layer; the other wiring line of the sub-line 40B is disposed in the third layer. In FIG. 25A, the wiring line in the first layer is not illustrated. The wiring lines in the second layer are hatched, and the wiring lines in the third layer are illustrated with relatively bold outlines. In FIG. 25A, the wiring lines in the second layer are illustrated as being thinner than the wiring lines in the third layer. However, both the wiring lines actually have almost the same width.

The main line 40A of the balanced-to-unbalanced transformer circuit 40 goes around clockwise substantially once along a square or rectangular outline from the first end T1 to the second end T2. The wiring line, in the third layer, of the sub-line 40B of the balanced-to-unbalanced transformer circuit 40 is disposed so as to almost completely overlap the main line 40A. The wiring line, in the first layer, of the sub-line 40B of the balanced-to-unbalanced transformer circuit 40 is disposed so as to almost completely overlap the wiring line in the third layer, which is not illustrated in FIG. 25A.

The main line 45A of the Ruthroff transmission line transformer 45 is disposed in the second wiring layer, which is the same as that of the main line 40A of the balanced-to-unbalanced transformer circuit 40. In plan view, the main line 45A of the Ruthroff transmission line transformer 45 is disposed laterally interior to the main line 40A of the balanced-to-unbalanced transformer circuit 40, so as to extend parallel to the main line 40A, and goes around counterclockwise substantially once from the third end T3 to the fourth end T4. Thus, the winding direction, in which the transmission line of the balanced-to-unbalanced transformer circuit 40 extends from the first end T1 to the second end T2, is opposite to the winding direction, in which the transmission line of the Ruthroff transmission line transformer 45 extends from the third end T3 to the fourth end T4.

The second end T2 of the main line 40A of the balanced-to-unbalanced transformer circuit 40 is connected to the third end T3 of the main line 45A of the Ruthroff transmission line transformer 45 through a wiring line disposed in the second wiring layer. That is, the main line 40A of the balanced-to-unbalanced transformer circuit 40 and the main line 45A of the Ruthroff transmission line transformer 45 are constituted by a series of conductor patterns in the same wiring layer.

The sub-line 45B of the Ruthroff transmission line transformer 45 is disposed in the third wiring layer so as to almost completely overlap the main line 45A. The third end T3 of the main line 45A of the Ruthroff transmission line transformer 45 is connected to the fourth end T4 of the sub-line 45B in the third layer through a via and a wiring line extending towards the fourth end T4.

The second end T2 of the sub-line 40B of the balanced-to-unbalanced transformer circuit 40 and the third end T3 of the sub-line 45B of the Ruthroff transmission line transformer 45 are connected to the ground potential. The first end T1 of the main line 40A of the balanced-to-unbalanced transformer circuit 40 and the first end T1 of the sub-line 40B are connected to the respective differential-signal input nodes at which the differential signals RFin+ and RFin− are received. The fourth end T4 of the main line 45A of the Ruthroff transmission line transformer 45 is connected to the output node from which the single-ended signal RFout is output.

Excellent effects of the fifth embodiment example will be described.

In the fifth embodiment example, the balanced-to-unbalanced transformer circuit 40 may transform differential signals to a single-ended signal, and the Ruthroff transmission line transformer 45 may perform impedance transformation on the single-ended signal. Further, the configuration, in which the main line 40A of the balanced-to-unbalanced transformer circuit 40 and the main line 45A of the Ruthroff transmission line transformer 45 are constituted by a series of conductor patterns in the same wiring layer, may achieve space savings of the balanced-to-unbalanced impedance transformer circuit 70, and may suppress occurrence of parasitic inductance.

Referring to the drawings of FIGS. 25B to 27B, balanced-to-unbalanced impedance transformer circuits according to modified examples of the fifth embodiment example will be described. The drawings of FIGS. 25B to 27B are schematic plan views of wiring patterns of the main lines 40A and the sub-lines 40B of the balanced-to-unbalanced transformer circuits 40 and the main lines 45A and the sub-lines 45B of the Ruthroff transmission line transformers 45, which are used in the balanced-to-unbalanced impedance transformer circuits 70 according to various modified examples of the fifth embodiment example. As in FIG. 25A, also in each drawing of FIGS. 25B to 27B, the wiring line in the first layer is not illustrated; the wiring lines in the second layer are hatched; the wiring lines in the third layer are illustrated by using relatively bold outlines.

In the modified example in FIG. 25B, the winding direction, in which the main line 45A and the sub-line 45B of the Ruthroff transmission line transformer 45 extend from the third end T3 to the fourth end T4, is opposite to the winding direction of the main line 45A and the sub-line 45B of the Ruthroff transmission line transformer 45 in the fifth embodiment example (FIG. 25A). Therefore, the winding direction, in which the transmission line of the balanced-to-unbalanced transformer circuit 40 extends from the first end T1 to the second end T2, is the same as the winding direction, in which the transmission line of the Ruthroff transmission line transformer 45 extends from the third end T3 to the fourth end T4.

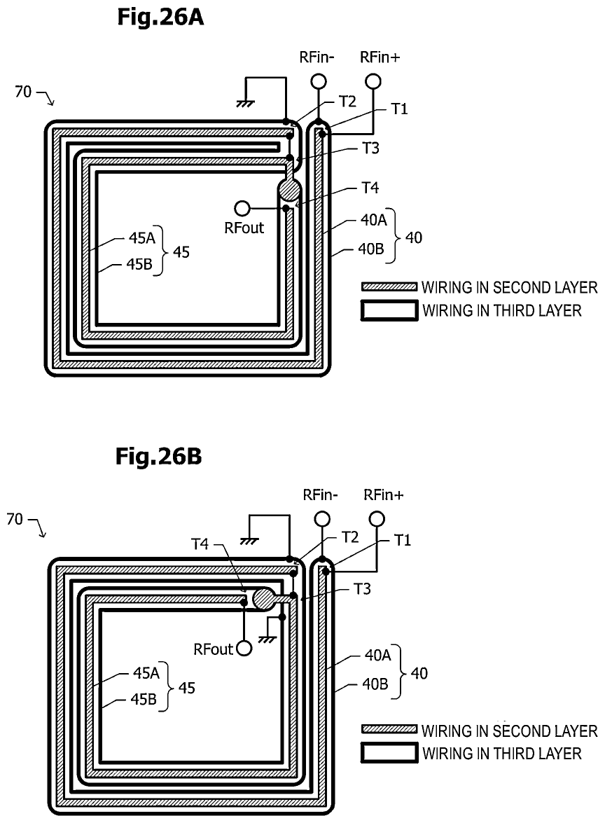

In the modified example in FIG. 26A, instead of the configuration, in which the main line 40A of the balanced-to-unbalanced transformer circuit 40 according to the fifth embodiment example (FIG. 25A) and the main line 45A of the Ruthroff transmission line transformer 45 are constituted by a series of conductor patterns, the wiring line, in the third layer, of the sub-line 40B of the balanced-to-unbalanced transformer circuit 40 and the sub-line 45B of the Ruthroff transmission line transformer 45 are constituted by a series of conductor patterns in the third layer. In the modified example in FIG. 26B, instead of the configuration, in which the main line 40A of the balanced-to-unbalanced transformer circuit 40 according to the modified example in FIG. 25B and the main line 45A of the Ruthroff transmission line transformer 45 are constituted by a series of conductor patterns, the wiring line, in the third layer, of the sub-line 40B of the balanced-to-unbalanced transformer circuit 40 and the sub-line 45B of the Ruthroff transmission line transformer 45 are constituted by a series of conductor patterns in the third layer. The second end T2 of the main line 40A of the balanced-to-unbalanced transformer circuit 40 is connected to the third end T3 of the main line 45A of the Ruthroff transmission line transformer 45. However, the size of the wiring line, which connects both the ends to each other, is different from that of the main line 40A and that of the sub-line 45B.

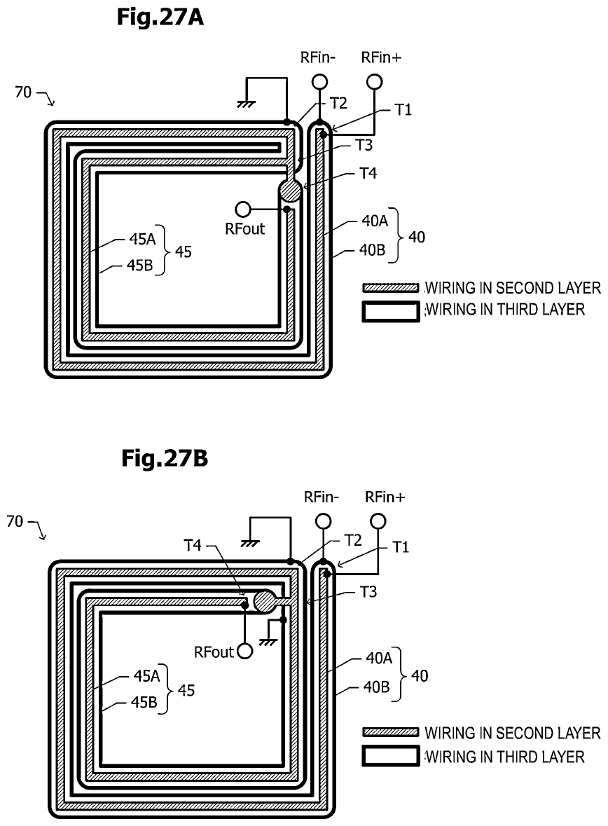

In the modified example in FIG. 27A, like the balanced-to-unbalanced transformer circuit 40 according to the fifth embodiment example (FIG. 25A), the main line 40A and the main line 45A of the Ruthroff transmission line transformer 45 are constituted by a series of conductor patterns. Further, the wiring line, in the third layer, of the sub-line 40B of the balanced-to-unbalanced transformer circuit 40 and the sub-line 45B of the Ruthroff transmission line transformer 45 are constituted by a series of conductor patterns in the third layer. In the modified example in FIG. 27B, like the balanced-to-unbalanced transformer circuit 40 according to the modified example in FIG. 25B, the main line 40A and the main line 45A of the Ruthroff transmission line transformer 45 are constituted by a series of conductor patterns. Further, the wiring line, in the third layer, of the sub-line 40B of the balanced-to-unbalanced transformer circuit 40 and the sub-line 45B of the Ruthroff transmission line transformer 45 are constituted by a series of conductor patterns in the third layer. The main lines are constituted by a series of conductor patterns, and so do the sub-lines. Thus, the balanced-to-unbalanced transformer circuit 40 and the Ruthroff transmission line transformer 45 may be constituted by a series of coupled transmission lines.

Also in the modified examples in FIGS. 25B to 27B, like the fifth embodiment example (FIG. 25A), space savings may be achieved and occurrence of parasitic inductance may be suppressed.

### Sixth Embodiment Example

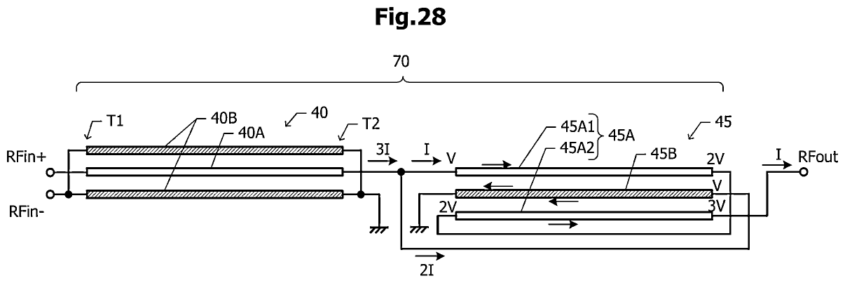

Referring to FIG. 28, a balanced-to-unbalanced impedance transformer circuit according to a sixth embodiment example will be described. The configuration common to the balanced-to-unbalanced impedance transformer circuit 70 according to the fifth embodiment example (FIG. 24) will not be described below.

FIG. 28 is an equivalent circuit diagram of a balanced-to-unbalanced impedance transformer circuit 70 according to the sixth embodiment example. In the fifth embodiment example (FIG. 24), the impedance transformation ratio of the Ruthroff transmission line transformer 45 is 4:1. In contrast, in the sixth embodiment example, the impedance transformation ratio of the Ruthroff transmission line transformer 45 is set to 9:1. The configuration of the Ruthroff transmission line transformer 45 will be described below.

The main line 45A of the Ruthroff transmission line transformer 45 includes a first part 45A1 and a second part 45A2 which are connected in series to each other. The first part 45A1 and the second part 45A2 are coupled to the sub-line 45B. Odd-mode currents flow through the main line 45A and the sub-line 45B. The arrows, which are opposite to each other and which are assigned to the main line 45A and the sub-line 45B, indicate flows of the odd-mode currents. Both the first part 45A1 and the second part 45A2 are coupled to the sub-line 45B. Thus, the magnitude of a current flowing through the sub-line 45B is double the magnitude of a current flowing through the main line 45A. The magnitude of a current is represented by a multiplier with the symbol, I. The magnitude of a current flowing through the main line 45A of the Ruthroff transmission line transformer 45 is one-third the magnitude of a current which is output from the second end T2 of the main line 40A of the balanced-to-unbalanced transformer circuit 40.

Each of the potential difference across the first part 45A1 and that across the second part 45A2 is equal to the potential difference across the sub-line 45B. The magnitude of a potential is represented by a multiplier with the symbol, V. The first part 45A1 and the second part 45A2 are connected in series to each other. Thus, the voltage of a single-ended signal, which is output from the main line 45A of the Ruthroff transmission line transformer 45, is triple the voltage of a single-ended signal received by the main line 45A.

The Ruthroff transmission line transformer 45 causes the current of a single-ended signal to be made one-third, and causes the voltage to be made triple. Thus, the impedance transformation ratio of 9:1 is achieved.

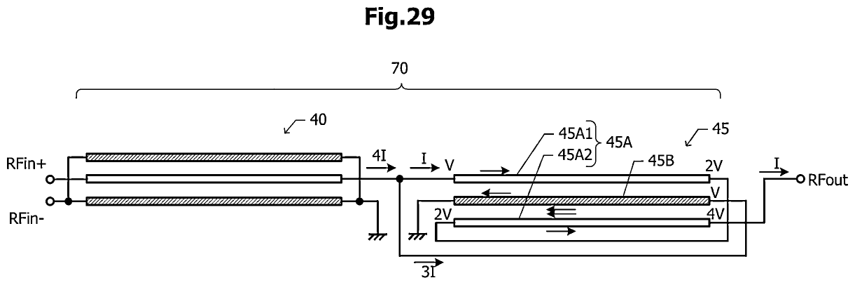

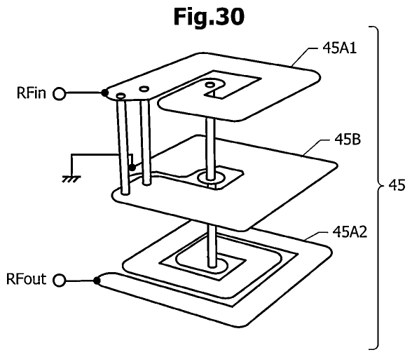

Referring to FIGS. 29 and 30, a balanced-to-unbalanced impedance transformer circuit according to a modified example of the sixth embodiment example will be described. FIG. 29 is an equivalent circuit diagram of a balanced-to-unbalanced impedance transformer circuit 70 according to the modified example of the sixth embodiment example.

In the sixth embodiment example, the line length of each of the first part 45A1 and the second part 45A2 of the main line 45A of the Ruthroff transmission line transformer 45 is substantially equal to that of the sub-line 45B. In contrast, in the modified example in FIGS. 29 and 30, the line length of the second part 45A2 of the main line 45A is approximately double that of the sub-line 45B. The line length ratio of the first part 45A1, the second part 45A2, and the sub-line 45B is 1:2:1. The line length ratio corresponds to the winding number ratio of the coils of a magnetic coupling transformer.

The first part 45A1 of the main line 45A and the sub-line 45B are coupled to each other. Thus, odd-mode currents, whose magnitudes are the same, flow through the first part 45A1 and the sub-line 45B. The arrows, which are opposite to each other and which are assigned to the main line 45A and the sub-line 45B, indicate flows of odd-mode currents. The number of arrows indicates the magnitude of an odd-mode current. The second part 45A2 of the main line 45A and the sub-line 45B are coupled to each other. Thus, odd-mode currents flow through both the lines. The magnitude of a current flowing through the sub-line 45B is double the magnitude of a current flowing through the second part 45A2. Therefore, a current, whose magnitude is triple that of a current flowing through the main line 45A, flows through the sub-line 45B. The magnitude of a current, which is output from the second end T2 of the main line 40A of the balanced-to-unbalanced transformer circuit 40, is quadruple that of a current flowing through the main line 45A of the Ruthroff transmission line transformer 45. In other words, the magnitude of the output current from the Ruthroff transmission line transformer 45 is one-fourth the magnitude of the input current.

The potential difference across the first part 45A1 of the main line 45A is equal to that across the sub-line 45B. The potential difference across the second part 45A2 is double that across the sub-line 45B. The magnitude of a potential is represented by a multiplier with the symbol, V. Therefore, the output voltage of the Ruthroff transmission line transformer 45 is quadruple the input voltage. Thus, the impedance transformation ratio of the Ruthroff transmission line transformer 45 is 16:1.

FIG. 30 is a schematic perspective view of the positional relationship of the main line 45A and the sub-line 45B of the Ruthroff transmission line transformer 45 used in the balanced-to-unbalanced impedance transformer circuit 70 according to the modified example (FIG. 29) of the sixth embodiment example. The first part 45A1 of the main line 45A is disposed in the first wiring layer; the second part 45A2 is disposed in the third wiring layer. The sub-line 45B is disposed in the second wiring layer. The first part 45A1 of the main line 45A, the sub-line 45B, and the second part 45A2 of the main line 45A overlap each other in plan view.

The first part 45A1 of the main line 45A has an annular pattern which goes around clockwise approximately once from the end portion on the outer peripheral side toward the end portion on the inner peripheral side; the second part 45A2 has a spiral shape which goes around clockwise approximately twice from the end portion on the inner peripheral side toward the end portion on the outer peripheral side. The end portion on the inner peripheral side of the first part 45A1 is connected to the end portion on the inner peripheral side of the second part 45A2. The sub-line 45B goes around counterclockwise approximately once from the end portion, which is connected to the end portion on the outer peripheral side of the first part 45A1, toward the end portion, which is connected to the ground potential. This structure causes the line length of the second part 45A2 of the main line 45A to be made approximately double the line length of the sub-line 45B.

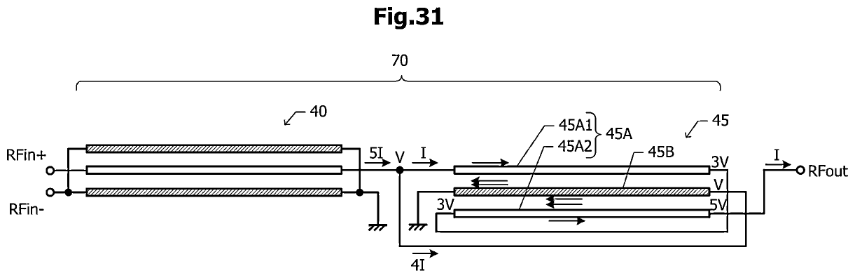

Referring to FIG. 31, a balanced-to-unbalanced impedance transformer circuit according to a different modified example of the sixth embodiment example will be described. FIG. 31 is an equivalent circuit diagram of a balanced-to-unbalanced impedance transformer circuit 70 according to the different modified example of the sixth embodiment example.

In the modified example in FIG. 31, the line length of each of the first part 45A1 and the second part 45A2 of the main line 45A of the Ruthroff transmission line transformer 45 is approximately double that of the sub-line 45B. This configuration causes the magnitude of a current flowing through the sub-line 45B to be quadruple the magnitude of a current flowing through the main line 45A. Thus, the magnitude of the output current of the Ruthroff transmission line transformer 45 is made one-fifth the magnitude of the input current. In addition, the magnitude of the output voltage of the Ruthroff transmission line transformer 45 is made quintuple the magnitude of the input voltage. As a result, the Ruthroff transmission line transformer 45 functions as an impedance transformer circuit having an impedance transformation ratio of 25:1.

As described above, the line lengths of the main line 45A and the sub-line 45B of the Ruthroff transmission line transformer 45 may be changed to achieve various impedance transformation ratios.

### Seventh Embodiment Example

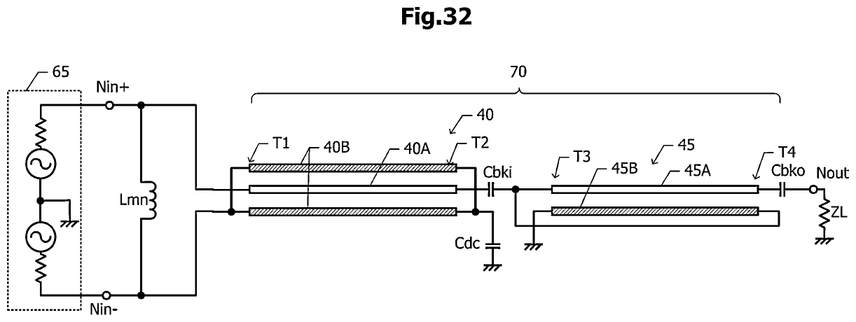

Referring to FIG. 32, a balanced-to-unbalanced impedance transformer circuit according to a seventh embodiment example will be described.

FIG. 32 is an equivalent circuit diagram of a balanced-to-unbalanced impedance transformer circuit 70 according to a seventh embodiment example. The balanced-to-unbalanced impedance transformer circuit 70 according to the seventh embodiment example includes the balanced-to-unbalanced transformer circuit 40 and the Ruthroff transmission line transformer 45 of the balanced-to-unbalanced impedance transformer circuit 70 (FIG. 24) according to the fifth embodiment example. The main line 40A and the sub-line 40B of the balanced-to-unbalanced transformer circuit 40 are connected, at the first end T1, to input nodes Nin+ and Nin−, respectively. Differential signals are input from a differential-signal source 65 to the input nodes Nin+ and Nin−.

An inductor Lmn is connected between the input node Nin+, which is one node, and the input node Nin−, which is the other node. The sub-line 40B is connected, at the second end T2, to the ground potential through a capacitor Cdc. The sub-line 40B is AC-grounded at the second end T2.

The main line 45A of the Ruthroff transmission line transformer 45 is connected, at the third end T3, to the second end T2 of the main line 40A of the balanced-to-unbalanced transformer circuit 40 through a capacitor Cbki. The main line 45A is connected, at the fourth end T4, to an output node Nout through a capacitor Cbko. The output node Nout is connected to the load ZL.

The balanced-to-unbalanced transformer circuit 40 transforms differential signals, which are input from the differential-signal source 65 to the input nodes Nin+ and Nin−, to a single-ended signal. The single-ended signal, which has been subjected to transformation by the balanced-to-unbalanced transformer circuit 40, is input to the Ruthroff transmission line transformer 45 through the capacitor Cbki. The Ruthroff transmission line transformer 45 performs impedance transformation on the input single-ended signal, and outputs the resulting signal through the capacitor Cbko from the output node Nout.

Excellent effects of the seventh embodiment example will be described.

In the seventh embodiment example, the inductor Lmn and the capacitors Cbki and Cbko function as an impedance matching device. Adjustment of the circuit constants of these reactance devices enables the impedance to be adjusted to a desired value. This enables the impedance, as seen from the differential-signal source 65 to the load side, to substantially match the output impedance of the differential-signal source 65.

A modified example of the seventh embodiment example will be described.

Instead of the inductor Lmn and the capacitors Cbki and Cbko which are used as an impedance matching device in the seventh embodiment example, other reactance devices may be used, or a passive circuit, in which multiple reactance devices are connected in series or in parallel, may be used. In addition, in the seventh embodiment example, the reactance devices are connected between the input nodes Nin+ and Nin−, between the balanced-to-unbalanced transformer circuit 40 and the Ruthroff transmission line transformer 45, and between the Ruthroff transmission line transformer and the load ZL. Alternatively, at a minimum of one of these positions, a reactance device may be connected.

### Eighth Embodiment Example

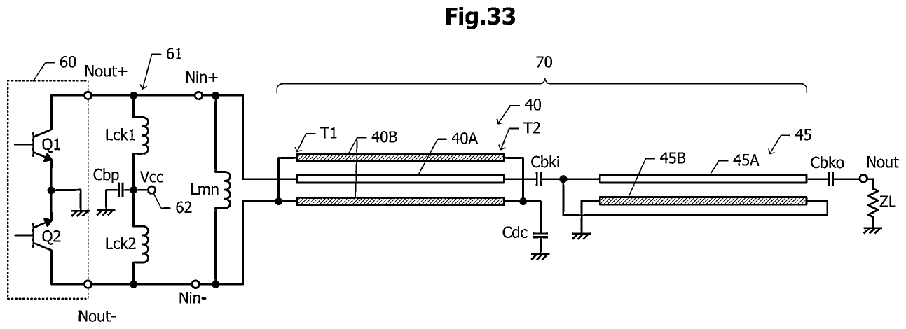

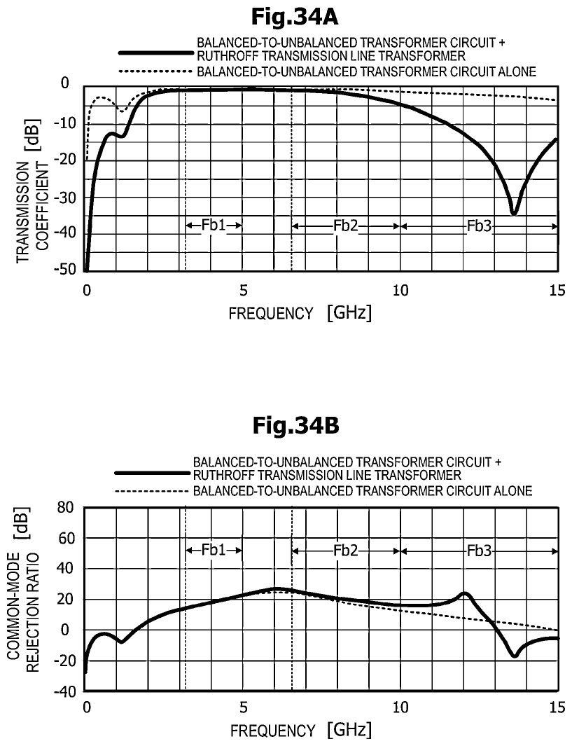

Referring to FIGS. 33, 34A, and 34B, a radio-frequency power amplifier according to an eighth embodiment example will be described.

FIG. 33 is an equivalent circuit diagram of a radio-frequency power amplifier according to the eighth embodiment example. The circuit configuration from the input nodes Nin+ and Nin−, to which differential signals are input, to the output node Nout, from which a single-ended signal is output, is the same as that of the balanced-to-unbalanced impedance transformer circuit 70 according to the seventh embodiment example. The radio-frequency power amplifier according to the eighth embodiment example further includes a differential-power amplifier circuit 60.

The differential-power amplifier circuit 60 includes two transistors Q1 and Q2. The transistors Q1 and Q2 may be, for example, heterojunction bipolar transistors. The emitters of the two transistors Q1 and Q2 are grounded. The collectors of the transistors Q1 and Q2 are connected to differential-signal output nodes Nout+ and Nout−, respectively. The differential-signal output nodes Nout+ and Nout− are connected to the differential-signal input nodes Nin+ and Nin−, respectively. The transistors Q1 and Q2 may be, for example, MISFETs (Metal-Insulator-Semiconductor Field Effect Transistors), MESFETs (Metal-Semiconductor Field Effect Transistors), or HEMTs (High Electron Mobility Transistors).

A power supply voltage Vcc is supplied from a power supply circuit 61 to the differential-signal output nodes Nout+ and Nout− of the differential-power amplifier circuit 60. The power supply circuit 61 includes a power terminal 62, choke coils Lck1 and Lck2, and a bypass capacitor Cbp. The power terminal 62 is connected to the differential-signal output nodes Nout+ and Nout− through the choke coils Lck1 and Lck2, respectively. Further, the power terminal 62 is further connected to the ground potential through the bypass capacitor Cbp.

The balanced-to-unbalanced transformer circuit 40 transforms differential signals, which are output from the differential-power amplifier circuit 60, to a single-ended signal. The inductor Lmn, the capacitors Cbki and Cbko, and the Ruthroff transmission line transformer 45 function as an impedance matching circuit which causes the output impedance of the differential-power amplifier circuit 60 to match the load impedance. The capacitors Cdc and Cbki have a function of DC-separating the power supply voltage Vcc, which is supplied from the power terminal 62, from the ground potential.

Excellent effects of the eighth embodiment example will be described.

The balanced-to-unbalanced transformer circuit 40 has a function of attenuating common-mode signals which are output from the differential-power amplifier circuit 60. Most of the even-order harmonic waves, which are output from the differential-power amplifier circuit 60, are common-mode signals. Thus, the balanced-to-unbalanced transformer circuit 40 has a function of attenuating the even-order harmonic waves.

The Ruthroff transmission line transformer 45 has a function of attenuating the third harmonic waves which are output from the differential-power amplifier circuit 60. Therefore, the balanced-to-unbalanced transformer circuit 40 and the Ruthroff transmission line transformer 45 function as a band-pass filter that attenuates the harmonic waves, which are output from the differential-power amplifier circuit 60, and that passes the fundamental waves.

The results of a simulation performed to confirm excellent effects of the radio-frequency power amplifier according to the eighth embodiment example will be described by referring to FIGS. 34A and 34B.

The operating frequency band Fb1 of the differential-power amplifier circuit 60 is set to 3.3 GHz or greater and 5 GHz or less (i.e., from 3.3 GHz to 5 GHz). The frequency band Fb2 of the second harmonic waves is 6.6 GHz or greater and 10 GHz or less (i.e., from 6.6 GHz to 10 GHz); the frequency band Fb3 of the third harmonic waves is 9.9 GHz or greater and 15 GHz or less (i.e., from 9.9 GHz to 15 GHz). The balanced-to-unbalanced transformer circuit 40 is designed so as to transform differential signals in the operating frequency band Fb1 to a single-ended signal. The Ruthroff transmission line transformer 45 is designed so as to perform optimum impedance transformation on a signal in the operating frequency band Fb1.

FIG. 34A is a graph of the simulation result of the transmission coefficients obtained in the case where differential signals are input to the differential-signal input nodes Nin+ and Nin− of the radio-frequency power amplifier according to the eighth embodiment example and where a single-ended signal is output from the output node Nout. The horizontal axis represents frequency in the units of [GHz]; the vertical axis represents the transmission coefficient in the units of [dB]. The solid line in the graph in FIG. 34A indicates the transmission coefficient of the balanced-to-unbalanced impedance transformer circuit 70 (FIG. 33) according to the eighth embodiment example; the dashed line indicates the transmission coefficient of the balanced-to-unbalanced transformer circuit 40 alone.

The balanced-to-unbalanced transformer circuit 40 alone fails to fully attenuate signals in the frequency band Fb3 of the third harmonic waves. However, the configuration, in which the Ruthroff transmission line transformer 45 is connected to the balanced-to-unbalanced transformer circuit 40, enables signals in the frequency band Fb3 of the third harmonic waves to be fully attenuated. This is because the Ruthroff transmission line transformer 45 has characteristics in which the input end is grounded in the frequency band of the third and fourth harmonic waves.

FIG. 34B is a graph of the simulation result of the common-mode rejection ratios of the radio-frequency power amplifier according to the eighth embodiment example. The horizontal axis represents frequency in the units of [GHz]; the vertical axis represents the common-mode rejection ratio in the units of [dB]. The solid line in the graph in FIG. 34B indicates the common-mode rejection ratio of the balanced-to-unbalanced impedance transformer circuit 70 (FIG. 33) according to the eighth embodiment example; the dashed line indicates the common-mode rejection ratio of the balanced-to-unbalanced transformer circuit 40 alone.

In the operating frequency band Fb1, the common-mode rejection ratio of about 20 dB is achieved. Also in the frequency band Fb2 of the second harmonic waves, the common-mode rejection ratio of about 20 dB, which is high enough, is obtained due to the balanced-to-unbalanced transformer circuit 40. Most of the second harmonic waves, which are output from the differential-power amplifier circuit 60 (FIG. 33), are common-mode signals. Thus, the second harmonic waves, which are output from the differential-power amplifier circuit 60, may be fully attenuated due to the balanced-to-unbalanced transformer circuit 40.

As described above, it is confirmed that the balanced-to-unbalanced impedance transformer circuit 70 according to the eighth embodiment example, in which the balanced-to-unbalanced transformer circuit 40 attenuating the common-mode second harmonic waves is cascade-connected to the Ruthroff transmission line transformer 45 attenuating the third harmonic waves, has a function as a band-pass filter which passes only signals in the operating frequency band Fb1 (the fundamental waves).

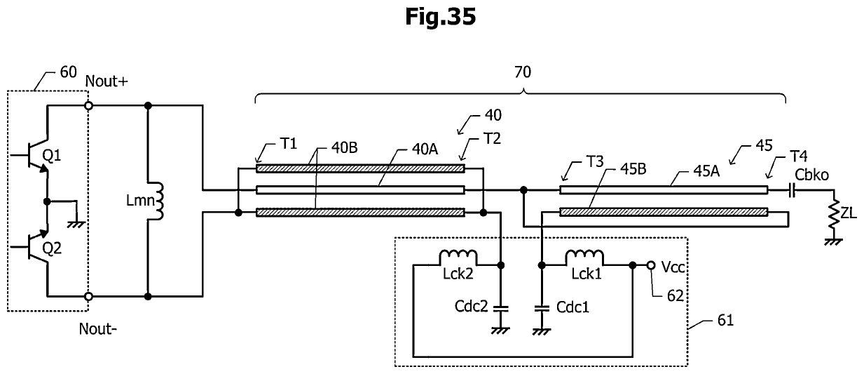

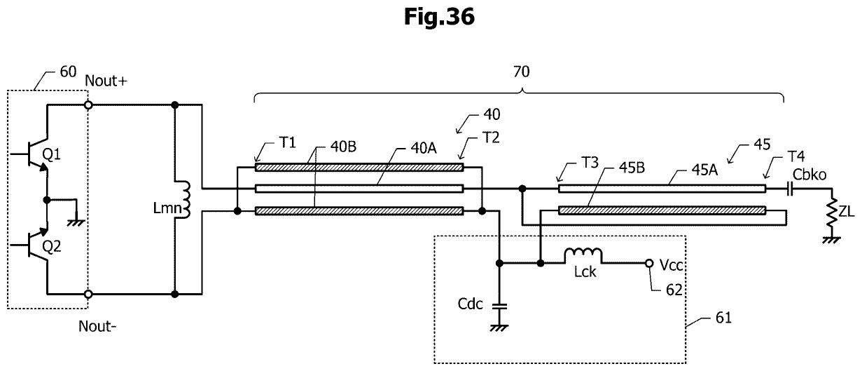

Referring to FIGS. 35 and 36, radio-frequency power amplifiers according to modified examples of the eighth embodiment example will be described. FIGS. 35 and 36 are equivalent circuit diagrams of radio-frequency power amplifiers according to the modified examples of the eighth embodiment example.

In the eighth embodiment example (FIG. 33), the power supply circuit 61 is directly connected to the differential-signal output nodes Nout+ and Nout− of the differential-power amplifier circuit 60. In contrast, in the modified examples in FIGS. 35 and 36, the power supply circuit 61 is connected to the differential-signal output nodes Nout+ and Nout− of the differential-power amplifier circuit 60 through the balanced-to-unbalanced impedance transformer circuit 70.

In the modified example in FIG. 35, the power terminal 62 is connected to the differential-signal output node Nout+, which is one of the nodes, through the choke coil Lck1, the sub-line 45B of the Ruthroff transmission line transformer 45, and the main line 40A of the balanced-to-unbalanced transformer circuit 40. Further, the power terminal 62 is connected to the differential-signal output node Nout-, which is the other node, through the choke coil Lck2 and the sub-line 40B of the balanced-to-unbalanced transformer circuit 40. The capacitor Cbki of the balanced-to-unbalanced impedance transformer circuit 70 according to the eighth embodiment example is excluded, and the main line 40A of the balanced-to-unbalanced transformer circuit 40 is directly connected to the main line 45A of the Ruthroff transmission line transformer 45.

The sub-line 40B of the balanced-to-unbalanced transformer circuit 40 is AC-connected, at the second end T2, to the ground potential through a capacitor Cdc2. The sub-line 45B of the Ruthroff transmission line transformer 45 is AC-connected, at the third end T3, to the ground potential through a capacitor Cdc1. The capacitors Cdc1 and Cdc2 have a function of DC-separating the power supply voltage Vcc from the ground potential.

In the modified example in FIG. 36, the sub-line 40B of the balanced-to-unbalanced transformer circuit 40 is directly connected, at the second end T2, to the third end T3 of the sub-line 45B of the Ruthroff transmission line transformer 45. The point, at which both the ends are connected, is AC-connected to the ground potential through the capacitor Cdc, and is connected to the power terminal 62 through a choke coil Lck. Like the modified example in FIG. 35, also in the present modified example, the power supply voltage Vcc is applied to the differential-signal output node Nout+, which is one of the nodes, through the choke coil Lck, the sub-line 45B of the Ruthroff transmission line transformer 45, and the main line 40A of the balanced-to-unbalanced transformer circuit 40. Further, the power supply voltage Vcc is applied to the differential-signal output node Nout−, which is the other node, through the choke coil Lck and the sub-line 40B of the balanced-to-unbalanced transformer circuit 40. The capacitor Cdc has a function of DC-separating the power supply voltage Vcc from the ground potential.

The embodiment examples described above are exemplary. Needless to say, partial replacement or combination of the configurations described in different embodiment examples may be made. Substantially the same operational effects caused by substantially the same configurations of multiple embodiment examples are not described in each embodiment example. Further, the present disclosure has no limitation from the embodiment examples. For example, it is obvious to those skilled in the art that various changes, improvements, combinations, and the like may be made.

What is claimed is:

1. A balanced-to-unbalanced transformer circuit comprising:
a transmission line including a main line and a sub-line which are coupled to each other,
wherein
the main line comprises at least one wiring line, and
the sub-line comprises a plurality of wiring lines connected in parallel to one another, the plurality of wiring lines being other than the at least one wiring line, and each of the plurality of wiring lines of the sub-line is coupled to the at least one wiring line of the main line.

2. The balanced-to-unbalanced transformer circuit according to claim 1, wherein
each of the at least one wiring line of the main line and the plurality of wiring lines of the sub-line is in a multilayer wiring substrate, and
the at least one wiring line of the main line is interposed between two of the plurality of wiring lines of the sub-line in a thickness direction of the multilayer wiring substrate.

3. The balanced-to-unbalanced transformer circuit according to claim 1, wherein
each of the at least one wiring line of the main line and the plurality of wiring lines of the sub-line is in a multilayer wiring substrate, and
two of the plurality of wiring lines of the sub-line are on both sides of the at least one wiring line of the main line in plan view of the multilayer wiring substrate.

4. The balanced-to-unbalanced transformer circuit according to claim 2, wherein
the at least one wiring line of the main line has a width smaller than the width of each of the plurality of wiring lines of the sub-line.

5. The balanced-to-unbalanced transformer circuit according to claim 1, wherein
the at least one wiring line of the main line comprises a plurality of wiring lines connected in parallel to one another,
the plurality of wiring lines of the main line is less than or equal to, in count, the plurality of wiring lines of the sub-line, and
at least one of the plurality of wiring lines of the main line is coupled to two of the plurality of wiring lines of the sub-line.

6. The balanced-to-unbalanced transformer circuit according to claim 3, wherein
the at least one wiring line of the main line has a width smaller than the width of each of the plurality of wiring lines of the sub-line.

7. The balanced-to-unbalanced transformer circuit according to claim 2, wherein
the at least one wiring line of the main line comprises a plurality of wiring lines connected in parallel to one another,
the plurality of wiring lines of the main line is less than or equal to, in count, the plurality of wiring lines of the sub-line, and
at least one of the plurality of wiring lines of the main line is coupled to two of the plurality of wiring lines of the sub-line.

8. A balanced-to-unbalanced impedance transformer circuit comprising:
a balanced-to-unbalanced transformer circuit that comprises a transmission line including a main line and a sub-line which are coupled to each other; and
a Ruthroff transmission line transformer that is connected to an output end, for a single-ended signal, of the balanced-to-unbalanced transformer circuit,
wherein the sub-line of the balanced-to-unbalanced transformer circuit comprises a plurality of wiring lines connected in parallel to one another, and each of the plurality of wiring lines of the sub-line is coupled to the main line of the balanced-to-unbalanced transformer circuit.

9. The balanced-to-unbalanced impedance transformer circuit according to claim 8, wherein
the Ruthroff transmission line transformer includes a different main line and a different sub-line which are coupled to each other, and
the main line and the sub-line of the balanced-to-unbalanced transformer circuit and the main line and the sub-line of the Ruthroff transmission line transformer comprise wiring lines in a common multilayer wiring substrate.

10. The balanced-to-unbalanced impedance transformer circuit according to claim 9, wherein
the main line of the balanced-to-unbalanced transformer circuit and the main line of the Ruthroff transmission line transformer are constituted by a series of conductor patterns in an identical wiring layer.

11. The balanced-to-unbalanced impedance transformer circuit according to claim 9, wherein
one of the plurality of wiring lines of the sub-line of the balanced-to-unbalanced transformer circuit and the sub-line of the Ruthroff transmission line transformer are constituted by a series of conductor patterns in an identical wiring layer.

12. The balanced-to-unbalanced impedance transformer circuit according to claim 8, further comprising:
a reactance device that is connected between differential-signal input nodes of the balanced-to-unbalanced transformer circuit.

13. The balanced-to-unbalanced impedance transformer circuit according to claim 8, further comprising:
a reactance device that is connected between the balanced-to-unbalanced transformer circuit and the Ruthroff transmission line transformer.

14. The balanced-to-unbalanced impedance transformer circuit according to claim 8, further comprising:
a reactance device that is connected between the Ruthroff transmission line transformer and a load.

15. A radio-frequency power amplifier comprising:
the balanced-to-unbalanced impedance transformer circuit according to claim 8;
a differential-power amplifier circuit that outputs differential signals from differential-signal output nodes; and
a power supply circuit that supplies power to the differential-power amplifier circuit,
wherein the differential-signal output nodes of the differential-power amplifier circuit are connected to differential-signal input nodes of the balanced-to-unbalanced transformer circuit of the balanced-to-unbalanced impedance transformer circuit.

16. The balanced-to-unbalanced impedance transformer circuit according to claim 10, wherein
one of the plurality of wiring lines of the sub-line of the balanced-to-unbalanced transformer circuit and the sub-line of the Ruthroff transmission line transformer are constituted by a series of conductor patterns in an identical wiring layer.

17. The balanced-to-unbalanced impedance transformer circuit according to claim 9, further comprising:
a reactance device that is connected between differential-signal input nodes of the balanced-to-unbalanced transformer circuit.

18. The balanced-to-unbalanced impedance transformer circuit according to claim 9, further comprising:
a reactance device that is connected between the balanced-to-unbalanced transformer circuit and the Ruthroff transmission line transformer.

19. The balanced-to-unbalanced impedance transformer circuit according to claim 9, further comprising:
a reactance device that is connected between the Ruthroff transmission line transformer and a load.

20. A radio-frequency power amplifier comprising:
the balanced-to-unbalanced impedance transformer circuit according to claim 9;
a differential-power amplifier circuit that outputs differential signals from differential-signal output nodes; and
a power supply circuit that supplies power to the differential-power amplifier circuit,
wherein the differential-signal output nodes of the differential-power amplifier circuit are connected to differential-signal input nodes of the balanced-to-unbalanced transformer circuit of the balanced-to-unbalanced impedance transformer circuit.
